(19) United States
(12) Patent Application Publication
(10) Pub. No.: US 2004/0236531 A1
(43) Pub. Date: Nov. 25, 2004

(54) Method for adaptively testing integrated circuits based on parametric fabrication data

(76) Inventor: Robert Madge, Portland, OR (US)

Correspondence Address: Leo J. Peters, LSI Logic Corporation, 1551 McCarthy Blvd., MS D-106, Milpitas, CA, 95035, US

(21) Appl. No.: 10/441,882

(22) Filed: May 19, 2003

(51) Int. Cl. G01R 15/00

(52) U.S. Cl. 702/118; 702/57

(57) ABSTRACT

A method of adaptively testing electronic circuits based on fabrication data includes steps for receiving as input fabrication data of the electronic circuits from at least one of electrical test and in-line inspection; calculating a process capability from the fabrication data; and selecting a test selection program based on the process capability to minimize testing cost and to verify performance specifications.

### BACKGROUND OF THE INVENTION

1. Field of the Invention

The present invention is directed to testing integrated circuits. More specifically, but without limitation thereto, the present invention is directed to identifying manufacturing defects and process variations in integrated circuits resulting from the fabrication process.

2. Description of the Prior Art

Previous approaches to identifying manufacturing defects and process variations in integrated circuits resulting from the fabrication process require extensive functional and parametric tests regardless of fabrication data.

### SUMMARY OF THE INVENTION

In one aspect of the present invention, a method of adaptively testing electronic circuits based on fabrication data includes steps for receiving as input fabrication data of the electronic circuits from at least one of electrical test and in-line inspection; calculating a process capability from the fabrication data; and selecting a test selection program based on the process capability to minimize testing cost and to verify performance specifications.

In another aspect of the present invention, a computer program product for adaptively testing electronic circuits based on fabrication data includes a medium for embodying a computer program for input to a computer; and a computer program embodied in the medium for causing the computer to perform the following functions:

(a) receiving as input fabrication data of the electronic circuits from at least one of electrical test in-line inspection, and in-line measurement;

(b) calculating a process capability from the fabrication data; and

(c) selecting a test selection program based on the process capability to minimize testing cost and to verify performance specifications.

### BRIEF DESCRIPTION OF THE DRAWINGS

The present invention is illustrated by way of example and not limitation in the accompanying figures, in which like references indicate similar elements throughout the several views of the drawings, and in which:

FIG. 1 illustrates a flow chart of a method of adaptively testing electronic circuits based on fabrication data according to an embodiment of the present invention.

### DESCRIPTION OF THE ILLUSTRATED EMBODIMENTS

Previous approaches to identifying manufacturing defects and process variations in integrated circuits resulting from the fabrication process require extensive functional and parametric tests regardless of fabrication data. Alternatively, tests limited to only structural testing may be performed that assume that parametric issues will be screened during electrical test (E-test) or by during fabrication by in-line measurement. Electrical test is typically performed during fabrication or immediately thereafter on discrete transistors, resistors and capacitors, usually in the scribeline on each wafer. The results of the electrical test are often provided by the foundry to the customer as a basis for acceptance of a wafer lot. In addition to the electrical test, in-line testing is performed that includes optical inspection and electrical inspection of product or structures using inspection tools to identify structural defects, process variations, and electrical faults. A combination of functional, parametric, and structural tests may be used to verify the performance characteristics of silicon dies in a wafer lot.

Many of the “at-spec” tests performed by automated test equipment (ATE), for example, at-speed functional tests, delay fault tests, input and output (I/O) tests, and phase-locked loop (PLL) tests, may be unnecessary if the parametric data or in-line inspection data from the fabrication process indicates that these tests have an extremely low probability of failing. Conversely, if the parametric data or in-line inspection data is marginal, indicating that a high fail rate is probable, then the quality of the product may be severely affected if the full range of “at-spec” tests is not performed during ATE testing in wafersort and final test.

As the trend continues toward the use of foundry silicon providers and the reduction of “at-spec” testing due to escalating costs, adaptive testing can advantageously eliminate unnecessary tests for low risk failure modes based on fabrication data, even though the fabrication data may be subject to variations not generally within the control of the integrated circuit manufacturer. Certain products may be more sensitive to some processing conditions than others, and may require more extensive testing when these processing conditions exist.

The extensive testing required by previous approaches to identifying manufacturing defects and process variations in integrated circuits may be significantly reduced by incorporating information available from the fabrication data to adapt the testing program to the process variations that occur during fabrication. In the present invention, the fabrication data from the foundry is used as a basis for determining which functional and parametric tests are needed to verify the performance characteristics of the actual product die. If the fabrication data is well controlled, then certain tests may be reduced or omitted. Conversely, if the fabrication data indicates poor margin or a high rate of defects, then more extensive testing is required.

In one aspect of the present invention, a method of adaptively testing electronic circuits based on fabrication data includes steps for receiving as input fabrication data of the electronic circuits from at least one of electrical test, in-line inspection, and in-line measurement; calculating a process capability from the fabrication data; and selecting a test selection program based on the process capability to minimize testing cost and to verify performance specifications.

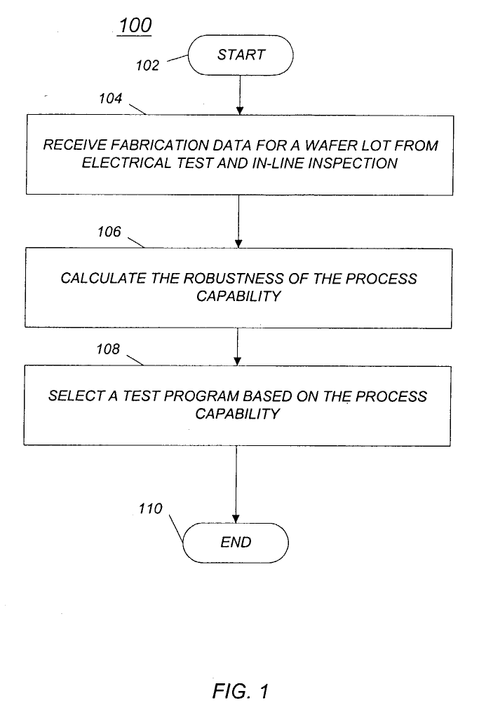

FIG. 1 illustrates a flow chart 100 of a method of adaptively testing electronic circuits based on fabrication data according to an embodiment of the present invention.

Step 102 is the entry point of the flow chart 100.

In step 104, fabrication data for a wafer lot from electrical test and in-line inspection is received as input. The fabrication data typically includes parameters critical to the performance of the product, such as frequency, leakage, and resistance measurements of each wafer in a lot. If the fabrication process is robust, that is, if the measured parameters are well within the specifications used to model the product performance, then the process has a high capability or yield.

In step 106, the robustness of the process capability is calculated from the electrical test and in-line inspection data constituting the fabrication data according to well-known statistical techniques as a function, for example, of a wafer, of a region of a wafer, of a number of wafers, and of a time period, such as a week or month. Adaptive test methods may be expanded to include adapting the testing based on results collected during the testing of a wafer, especially as wafer size is increased. Several factors may be used singly or in combination to calculate the robustness of the process capability, for example, Cp or Cpk, critical dimensions or thicknesses, Vtn, Vtp, Vtn/Vtp ratio, metal resistance, via resistance, and percentage of failed via chains. Cp and Cpk are both measures of the standard deviation of a parameter with respect to the specifications window, that is, a range of acceptable values.

For example, a value of Cp or Cpk greater than 1.33 is representative of a robust fabrication process. A combination of tests may be used if the product is sensitive to more than one parameter. For example, Vtn (N-channel threshold voltage) and Vtp (P-channel threshold voltage) may not be as important in some products as the Vtn/Vtp ratio. If one or the other is significantly higher than the other, however, then full testing may be required to screen the product.

The resistance of vias may be measured during electrical test or in-line inspection, and if the measured values are high relative to the model specifications, then the product may require special testing for quality and performance. If the vias demonstrate a low fail percentage and good resistance values, less testing of the actual product is required. The method of the present invention for determining the number of required tests from previous test results may be applied to other types of testing to practice the invention within the scope of the appended claims.

The user may also define other parameters and ratios to calculate the process capability, and the factors used to calculate the process capability may be adjusted periodically to ensure that the calculation of the robustness of the process capability correctly indicates the required amount of ATE testing for the desired level of quality.

In step 108, a test selection program selects a test program selected based on the process capability calculated in step 106 to minimize testing cost and to verify performance specifications. The test program is selected to exercise the important features of a specific product, for example, operating frequency limits, and may vary depending on the sensitivities of the product and on user defined input. The test program is selected according to a range of options for testing a wafer, wafer lot, or series of wafer lots for a specific product. The range of options may include, for example, full testing, defect testing only (no parametric tests), low pin-count testing (no I/O tests), structural testing only (no functional tests), mixed signal testing, I/O testing, at-speed testing, delay fault testing, built-in self testing, IDDQ testing, memory testing, and reduced vector testing, and so on. The options corresponding to each wafer, wafer lot, or wafer lot series over time may be varied during the process according to well-known computer programming techniques to fine tune the test program for the lowest testing costs while ensuring that the required performance specifications are met. For example, if the design engineer knows that the product is sensitive to a high value of Vtn and a low value of Vtp, then the test program may be modified accordingly to ensure that full parametric testing is performed if the electrical test data indicates a high value of Vtn and a low value of Vtp. If the electrical test data indicates a nominal value of Vtn and a nominal value of Vtp, then lower cost test options may be applied. By selecting the minimum set of test options required to verify specified performance, the test selection program adaptively determines the test program best suited for a specific product.

Step 110 is the exit point of the flow chart 100.

Although the method of the present invention illustrated by the flowchart description above is described and shown with reference to specific steps performed in a specific order, these steps may be combined, sub-divided, or reordered without departing from the scope of the claims. Unless specifically indicated herein, the order and grouping of steps is not a limitation of the present invention.

The method illustrated in the flowchart description above may be embodied in a computer program product and implemented by a computer according to well known programming techniques.

In another aspect of the present invention, a computer program product for adaptively testing electronic circuits based on fabrication data includes a medium for embodying a computer program for input to a computer; and a computer program embodied in the medium for causing the computer to perform the following functions:

(a) receiving as input fabrication data of the electronic circuits from at least one of electrical test and in-line inspection;

(b) calculating a process capability from the fabrication data; and

(c) selecting a test selection program based on the process capability to minimize testing cost and to verify performance specifications.

While the invention herein disclosed has been described by means of specific embodiments and applications thereof, numerous modifications and variations may be made thereto by those skilled in the art without departing from the scope of the invention set forth in the following claims.

What is claimed is:

1. A method of adaptively testing electronic circuits based on fabrication data comprising steps for:
(a) receiving as input fabrication data of the electronic circuits from at least one of electrical test and in-line inspection;
(b) calculating a process capability from the fabrication data; and
(c) selecting a test selection program based on the process capability to minimize testing cost and to verify performance specifications.

2. The method of claim 1 wherein step (a) further includes receiving at least one of Cp, Cpk, Vtn, Vtp, Vtn/Vtp, metal resistance, via resistance, and percentage of failed via chains.

3. The method of claim 1 wherein step (b) further includes measuring a standard deviation of a parameter with respect to a specifications window.

4. The method of claim 1 wherein step (b) further includes calculating the process capability as a function of at least one of a wafer, a number of wafers, and a time period.

5. The method of claim 1 wherein step (c) further includes selecting the test program to exercise selected features of a specific product.

6. The method of claim 1 wherein step (c) further includes selecting the test program from a range of options including at least one of full testing, defect testing, low pin-count testing, structural testing, mixed signal testing, I/O testing, at-speed testing, delay fault testing, built-in self testing, IDDQ testing, memory testing, and reduced vector testing.

7. A computer program product for adaptively testing electronic circuits based on fabrication data comprising:
a medium for embodying a computer program for input to a computer; and
a computer program embodied in the medium for causing the computer to perform the following functions:
(a) receiving as input fabrication data of the electronic circuits from at least one of electrical test and in-line inspection;
(b) calculating a process capability from the fabrication data; and
(c) selecting a test selection program based on the process capability to minimize testing cost and to verify performance specifications.

8. The computer program product of claim 7 wherein function (a) further includes receiving at least one of Cp, Cpk, Vtn, Vtp, Vtn/Vtp, metal resistance, via resistance, and percentage of failed via chains.

9. The computer program product of claim 7 wherein function (b) further includes measuring a standard deviation of a parameter with respect to a specifications window.

10. The computer program product of claim 7 wherein function (b) further includes calculating the process capability as a function of at least one of a wafer, a number of wafers, and a time period.

11. The computer program product of claim 7 wherein function (c) further includes selecting the test program to exercise selected features of a specific product.

12. The computer program product of claim 7 wherein function (c) further includes selecting the test program from a range of options including at least one of full testing, defect testing, low pin-count testing, and structural testing.
